(19) United States
(12) Patent Application Publication
(10) Pub. No.: US 2014/0131074 A1
(43) Pub. Date: May 15, 2014

(54) WIRING SUBSTRATE AND METHOD FOR MANUFACTURING WIRING SUBSTRATE

(71) Applicant: IBIDEN CO., LTD., Ogaki-shi (JP)

(72) Inventors: Teruyuki Ishihara, Ogaki-shi (JP); Michimasa Takahashi, Ogaki-shi (JP)

(73) Assignee: IBIDEN CO., LTD., Ogaki-shi (JP)

(21) Appl. No.: 14/076,554

(22) Filed: Nov. 11, 2013

(30) Foreign Application Priority Data
Nov. 9, 2012 (JP) 2012-247833

(51) Int. Cl. H05K 3/00

(52) U.S. Cl. CPC H05K 3/007
USPC 174/255; 29/850

(57) ABSTRACT

A wiring substrate has a frame including a metal material and having a connecting portion, and a piece substrate connected to the connecting portion of the frame and having a metal pattern. The metal pattern of the piece substrate has a contour which is corresponding to an outer edge of the connecting portion of the frame.

### CROSS-REFERENCE TO RELATED APPLICATIONS

The present application is based upon and claims the benefit of priority to Japanese Patent Application No. 2012-247833, filed Nov. 9, 2012, the entire contents of which are incorporated herein by reference.

### BACKGROUND OF THE INVENTION

1. Field of the Invention

The present invention relates to a wiring substrate and a method for manufacturing the wiring substrate.

2. Description of Background Art

In a wiring board manufacturing process, a buildup layer may be formed or a component may be mounted simultaneously for multiple piece substrates of the multipiece substrate.

For example, JP 2011-23657 A describes a multipiece substrate that includes a frame having space to accommodate piece substrates and multiple piece substrates cut out from another frame different from the aforementioned frame. The entire contents of this publication are incorporated herein by reference.

### SUMMARY OF THE INVENTION

According to one aspect of the present invention, a wiring substrate has a frame including a metal material and having a connecting portion, and a piece substrate connected to the connecting portion of the frame and having a metal pattern. The metal pattern of the piece substrate has a contour which is corresponding to an outer edge of the connecting portion of the frame.

According to another aspect of the present invention, a method for manufacturing a wiring substrate includes providing a frame including a metal material and having a connecting portion, providing a base component having a corresponding portion formed to be cut and form a piece substrate, forming a metal pattern on the base component such that the metal pattern is formed to correspond to an outer edge of a fitting portion of the corresponding portion for connecting with the connecting portion of the frame, irradiating laser along a border formed between the metal pattern and the base component such that the piece substrate including the corresponding portion is cut out from the base component, and engaging the fitting portion of the piece substrate to the connecting portion of the frame such that the piece substrate is connected to the frame.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a plan view illustrating a wiring substrate;

FIG. 2 is a perspective view illustrating a frame;

FIG. 3 is a flowchart illustrating a series of processes performed to manufacture a wiring substrate;

FIG. 4 is a plan view illustrating a work piece;

FIG. 5 is a cross-sectional view illustrating the work piece;

FIG. 6 is a diagram illustrating a metal pattern formed on the work piece;

FIG. 7 is a diagram illustrating a sequence for cutting a matching portion as the piece substrate;

FIG. 8 is a diagram illustrating how the matching portion is cut out from the work piece;

FIG. 9 is a perspective view illustrating the piece substrate cut out from the work piece;

FIG. 10 is a diagram illustrating a sequence of accommodating the piece substrate in the frame;

FIG. 11 is a diagram illustrating a pressing process for the wiring substrate;

FIG. 12 is a diagram illustrating a flatness test for the wiring substrate;

FIG. 13 is a diagram illustrating an effect of the wiring substrate according to an embodiment of the invention;

FIG. 14 is a diagram illustrating an effect of the wiring substrate according to the embodiment of the invention;

FIG. 15 is a diagram illustrating an effect of the wiring substrate according to the embodiment of the invention; and

FIG. 16 is a diagram illustrating an effect of the wiring substrate according to the embodiment of the invention;

FIG. 17 is a diagram illustrating a modified example of a metal pattern according to an embodiment the invention;

FIG. 18 is a diagram illustrating another modified example of a metal pattern according to an embodiment of the invention;

FIG. 19 is a diagram illustrating yet another modified example of a frame according to an embodiment of the invention;

FIG. 20 is a diagram illustrating yet another modified example of a frame according to an embodiment of the invention;

FIG. 21 is a diagram illustrating yet another modified example of a piece substrate according to an embodiment of the invention; and

FIG. 22 is a diagram illustrating yet another modified example of a wiring substrate according to an embodiment of the invention.

### DETAILED DESCRIPTION OF THE EMBODIMENTS

The embodiments will now be described with reference to the accompanying drawings, wherein like reference numerals designate corresponding or identical elements throughout the various drawings.

In the following description, a coordinate system including X, Y, and Z axes perpendicular to each other is employed.

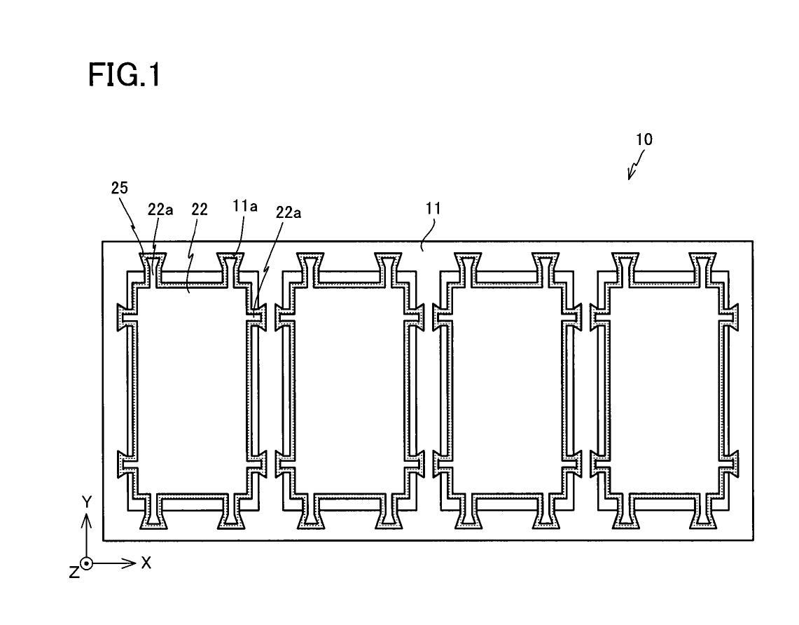

FIG. 1 illustrates a wiring substrate 10 according to the present embodiment. This wiring substrate 10 has a frame 11 and four piece substrates 22.

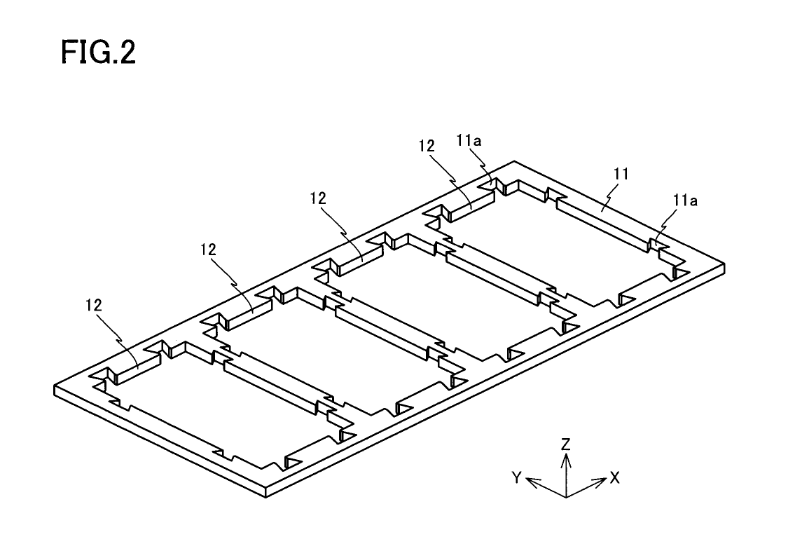

FIG. 2 is a perspective view illustrating the frame 11. As illustrated in FIG. 2, the frame 11 has a rectangular shape with its longitudinal side set in a direction X. The frame 11 has four rectangular openings 12 arranged side by side along a direction X. An inner wall surface of the opening 12 has multiple concave portions (11a). Each of the concave portions (11a) is narrowed toward the inside of the frame 11. This frame 11 is manufactured, for example, by forming a sheet metal from an aluminum steel sheet.

Returning to FIG. 1, the piece substrate 22 is a rectangular multilayer wiring board with its longitudinal side set in a direction Y. The piece substrate 22 has eight fitting portions (22a) formed in the vicinity of the four corners respectively and connected to the concave portions (11a) of the frame 11. In addition, a metal pattern 25 is formed along the outer edge of the piece substrate 22 on the surface of the piece substrate 22. Each of the piece substrates 22 is accommodated in the opening 12 and is fixed in the frame 11 by inserting each of the eight fitting portions 22a into their respective concave portions (11a) of the frame 11.

According to the present embodiment, the frame 11 has a thickness of approximately 0.75 mm, and the piece substrate 22 has a thickness of approximately 0.78 mm. Therefore, the thickness of the frame 11 is thinner than that of the piece substrate 22.

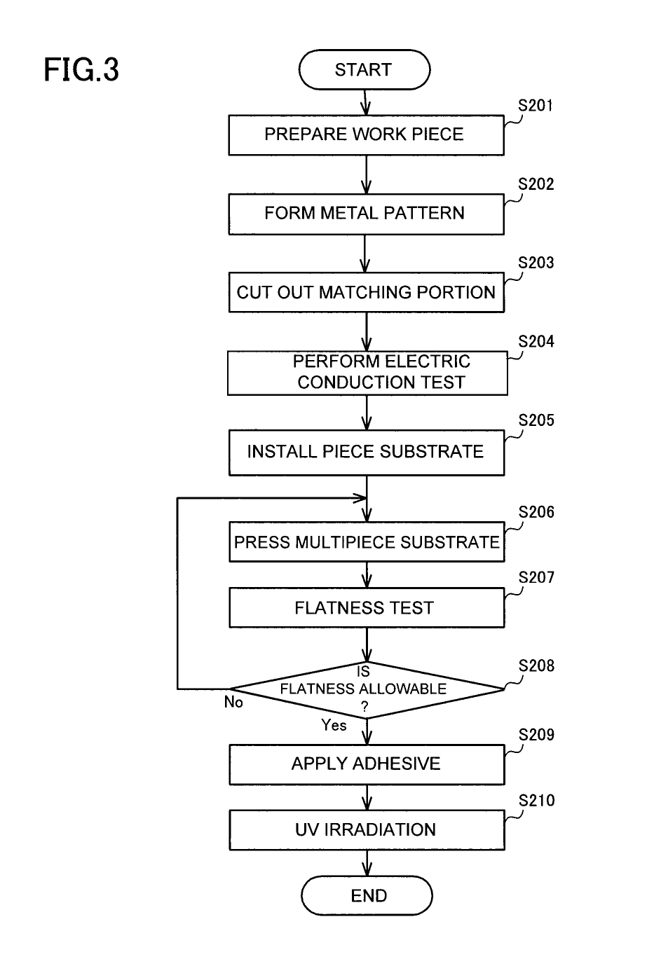

Next, a method for manufacturing a wiring substrate 10 according to the present embodiment will be described with reference to the flowchart in FIG. 3 and FIGS. 4 to 12. FIG. 3 is a flowchart illustrating a series of processes performed to manufacture the wiring substrate 10.

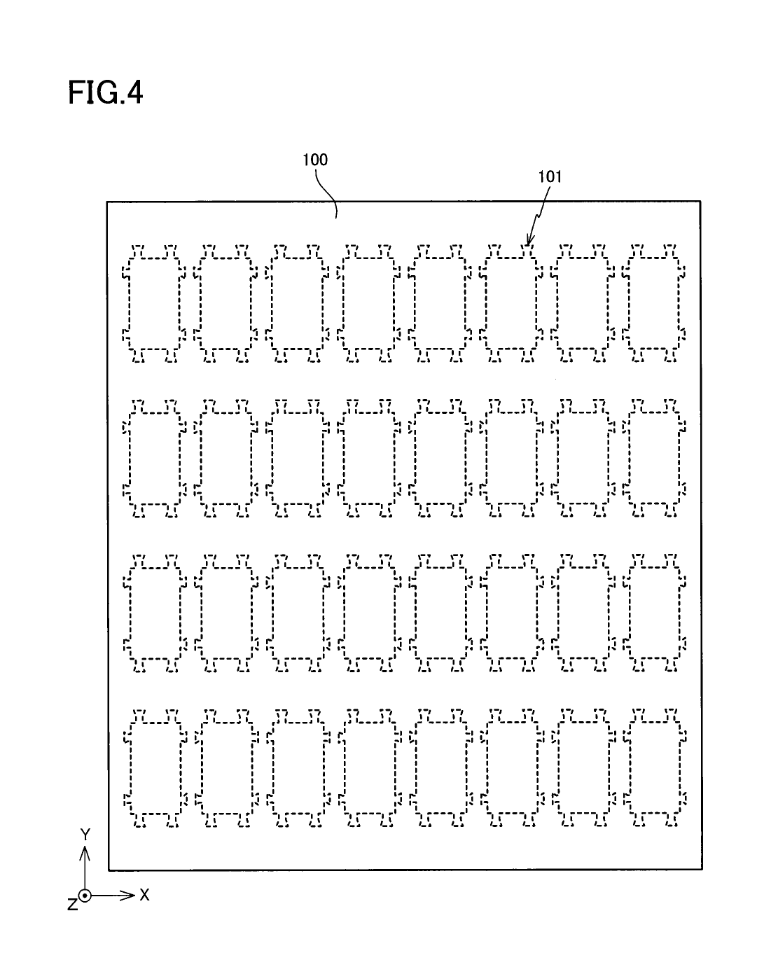

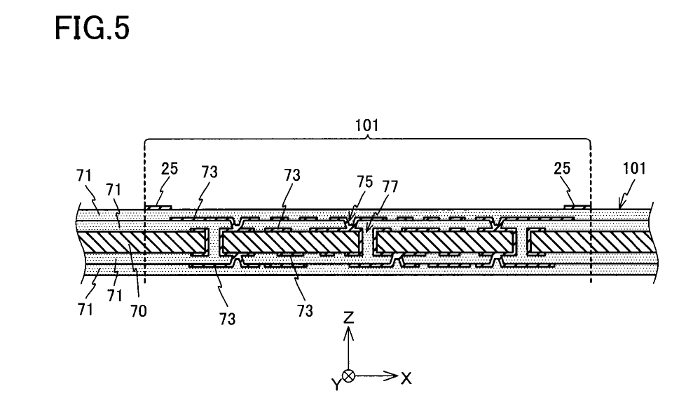

First, in step S201, a rectangular work piece 100 serving as a base material of the piece substrate 22 is prepared as illustrated in FIG. 4. FIG. 5 is a cross-sectional view illustrating the work piece 100. As illustrated in FIG. 5, the work piece 100 includes a base material 70, and an insulation layer 71 and a conductive layer 73 laminated on the surface of the base material 70. In addition, the base material 70 has a through-hole conductor 77 formed to connect the conductive layers 73 to each other, and the insulation layer 71 has a via conductor 75 formed to connect the conductive layers 73 to each other.

The base material 70 is made of, for example, a glass cloth, non-woven fabric of aramid fiber, paper or the like. The insulation layer 71 is made of prepreg obtained by impregnating an epoxy resin, a polyimide resin, a phenol-based resin or the like. The conductive layer 73 is made of a copper foil or plating provided on a surface of the base material 70 or a surface of the insulation layer 71.

The portion indicated by the dotted line in FIG. 4 is a portion corresponding to the piece substrate 22, and the cutting portion obtained by cutting the work piece 100 along the dotted line in FIG. 4 becomes the piece substrate 22. In the following description, for the sake of convenience, the portion enveloped by the dotted line in FIG. 4 is referred to as a matching portion 101 of the work piece 100. As illustrated in FIG. 5, the conductive layer 73, the through-hole conductor 77, and the via conductor 75 are typically formed in the matching portion 101 of the work piece 100.

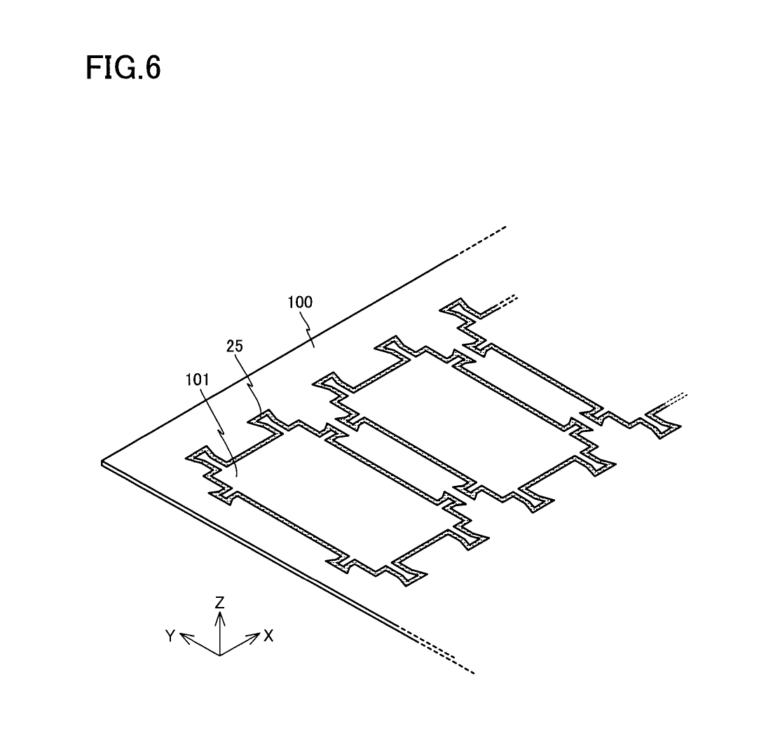

Then, in step S202, as illustrated in FIGS. 5 and 6, a metal pattern 25 is formed along an outer edge of the matching portion 101 defined in the work piece 100. Specifically, electroless plating and electrolytic plating are performed for the surface of the matching portion 101 to form a plating film on the surface of the matching portion 101. Then, by etching this plating film, a metal pattern 25 is formed along the outer edge of the matching portion 101.

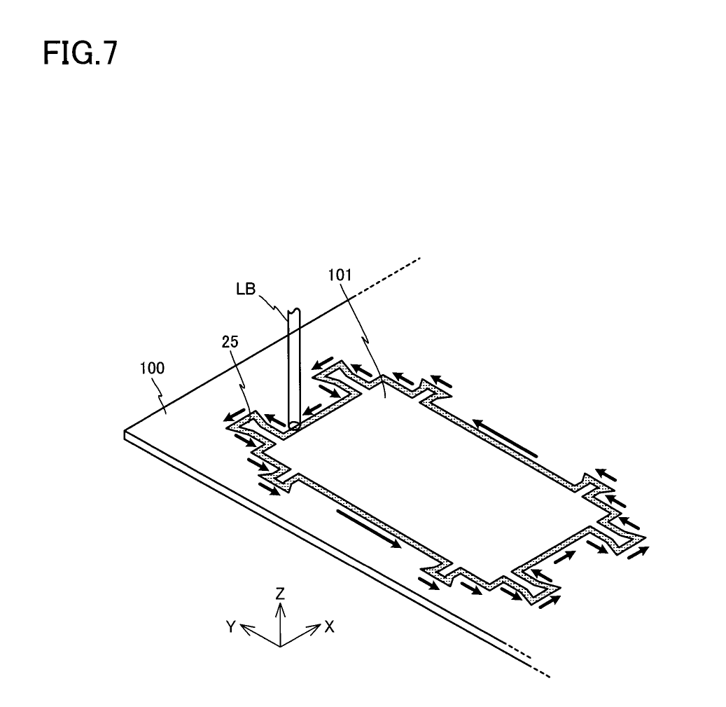

Then, in step S203, the matching portion 101 is cut out from the work piece 100 together with the metal pattern 25. Specifically, as illustrated in FIG. 7, laser beam (LB) is irradiated onto the outer edge of the metal pattern 25 and the boundary of the work piece 100. At this stage, a beam spot of the laser beam (LB) is formed across the metal pattern 25 and the work piece 100. Then, as indicated by the arrow in FIG. 7, the laser beam (LB) is moved relative to the work piece 100 so that the beam spot of the laser beam (LB) moves along the outer edge of the metal pattern 25 and the boundary of the work piece 100. As a result, the area of the work piece 100 that is not covered by the metal pattern 25 is melted, and the matching portion 101 is cut out from the work piece 100 together with the metal pattern 25. Various light sources may be employed as a light source of the laser beam (LB). For example, a CO₂ laser may be employed.

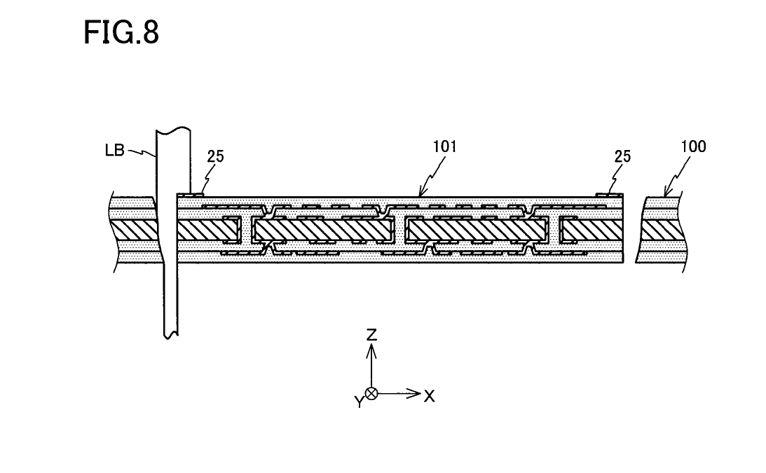

FIG. 8 is a diagram illustrating a state that the matching portion 101 is cut out from the work piece 100 together with the metal pattern 25. As illustrated in FIG. 8, if the laser beam (LB) directed from the upper side (+Z side) of the work piece 100 to the lower side (−Z side) is irradiated onto the work piece 100, the incident laser beam (LB) irradiated at the metal pattern 25 is blocked by the metal pattern 25. Meanwhile, the incident laser beam (LB) irradiated at the upper surface of the work piece 100 melts the work piece 100 on the outer side of the metal pattern 25.

Accordingly, by moving the laser beam (LB) relative to the work piece so that the beam spot of the laser beam (LB) moves along the outer edge of the metal pattern 25 and the boundary of the work piece 100, the work piece 100 and the matching portion 101 are separated along the outer edge of the metal pattern 25. As a result, the matching portion 101 is cut out from the work piece 100. The matching portion 101 cut out from the work piece 100 corresponds to the piece substrate 22 accommodated in the frame 11.

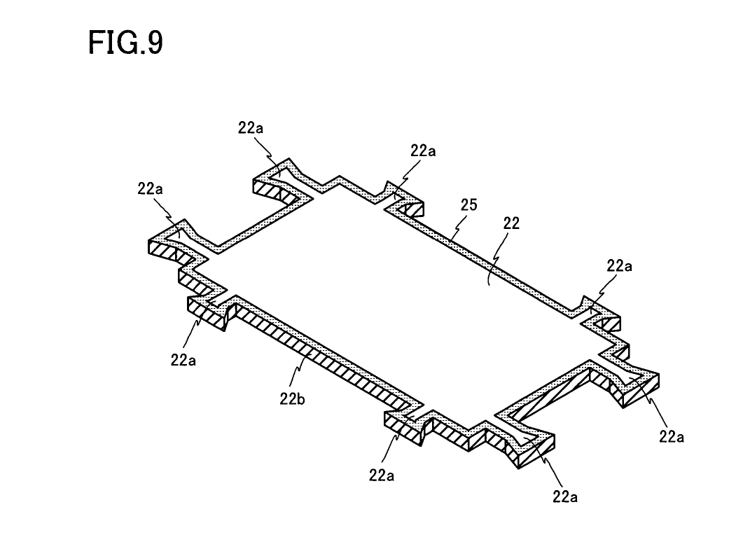

FIG. 9 is a perspective view illustrating the piece substrate 22 cut out from the work piece 100. As illustrated in FIG. 9, the metal pattern 25 is formed on the upper surface of the piece substrate 22 along the outer edge of the piece substrate 22. In addition, the fitting portions (22a) protruding to the outside from the main body of the piece substrate 22 are formed respectively in the vicinities of the four corners of the piece substrate 22. A contour of the fitting portion (22a) substantially corresponds to a contour of the concave portion (11a) of the frame 11. That is, the outer edge of the metal pattern 25 substantially corresponds to the contour of the concave portion (11a) of the frame 11. Furthermore, a cutting plane (22b) of the piece substrate 22 is formed along the metal pattern 25. The cutting plane (22b) is a flat surface substantially perpendicular to the upper surface (+Z side surface) of the piece substrate 22.

Through the method described above, multiple matching portions 101 are cut out from the work piece 100 as the piece substrate 22.

Then, in step S204, an electric conduction test is performed for each of the piece substrates 22 manufactured by cutting out the matching portions 101 from the work piece 100. If there is an abnormality in the piece substrate 22 found as a result of the electric conduction test, the abnormal piece substrate 22 is excluded.

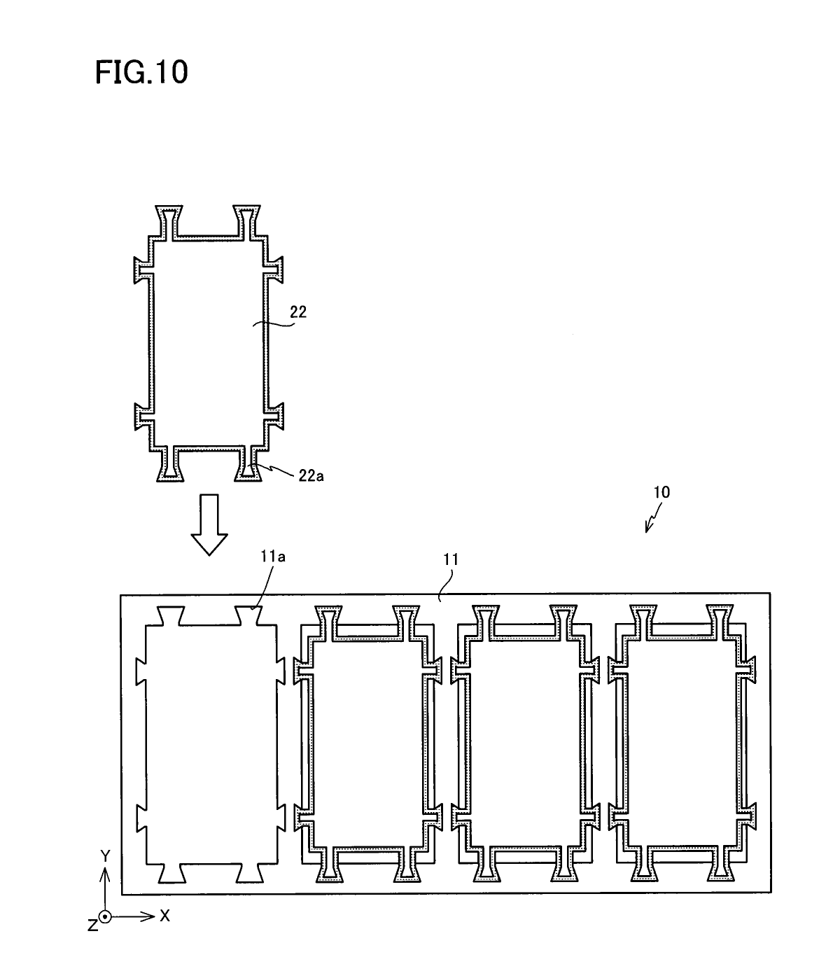

Then, in step S205, the piece substrate 22 is accommodated in the frame 11. FIG. 10 is a diagram illustrating how the piece substrate 22 is accommodated in the frame 11. As recognized from FIG. 10, the piece substrate 22 is accommodated by inserting eight fitting portions (22a) formed in the piece substrate 22 into the concave portions (11a) formed in the frame 11. The piece substrate 22 is integrated into the frame 11 by inserting the fitting portions (22a) into the concave portions (11a) of the frame 11. According to the present embodiment, four piece substrates 22 are accommodated in a single frame 11.

Then, in step S206, as illustrated in FIG. 11, the wiring substrate 10 (multipiece substrate) is pressed using a press machine 305 to press a connecting portion between the piece substrate 22 and the concave portion (11a) of the frame 11 to flatten the surface.

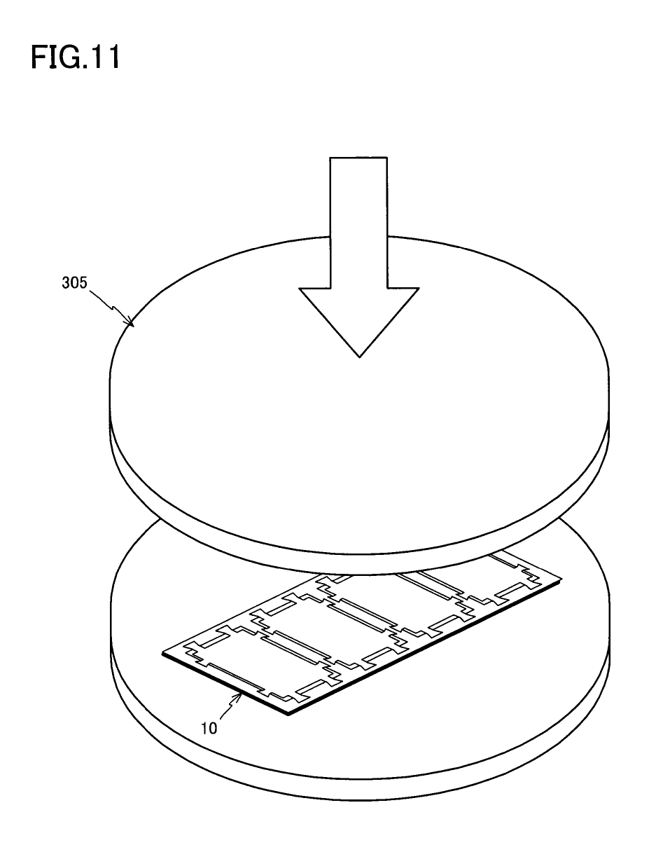

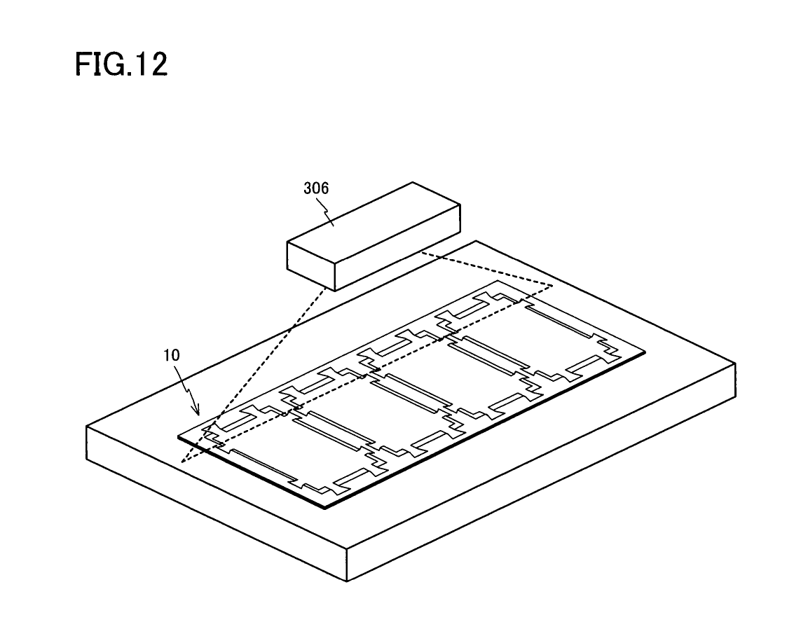

Then, in step S207, as illustrated in FIG. 12, the flatness of the wiring substrate 10 is tested using a laser displacement gauge 306. In addition, in step S208, it is determined whether or not that degree of flatness is allowable. If it is determined that the flatness is not allowable in step S208 (NO in step S208), the process returns to step S206, and steps S206 to 5208 are repeated.

Meanwhile, if it is determined that the flatness is allowable in step S208 (YES in step S208), the process advances to step 5209.

In step S209, a UV-curable adhesive is applied to a border between the concave portion (11a) of the frame 11 and the fitting portion (22a) formed in the piece substrate 22. This adhesive enters a gap between the inner wall surface of the concave portion (11a) formed in the frame 11 and a side surface of the fitting portion (22a) formed in the piece substrate 22.

Then, in step S210, an ultraviolet (UV) ray is irradiated onto the concave portion (11a) of the frame 11 and the fitting portion (22a) of the piece substrate 22. As a result, the applied adhesive is cured, and the frame 11 and the piece substrate 22 are securely bonded to each other, so that the wiring substrate 10 of FIG. 1 is completely manufactured.

As described above, in the wiring substrate 10 according to the present embodiment, the piece substrate 22 is accommodated in the frame 11 made of aluminum having a higher rigidity than that of a material of the piece substrate 22. Therefore, warping of the piece substrate 22 is suppressed even when the piece substrate 22 is heated to a temperature higher than a glass transition temperature of the resin in the piece substrate 22 during a reflow process and the like.

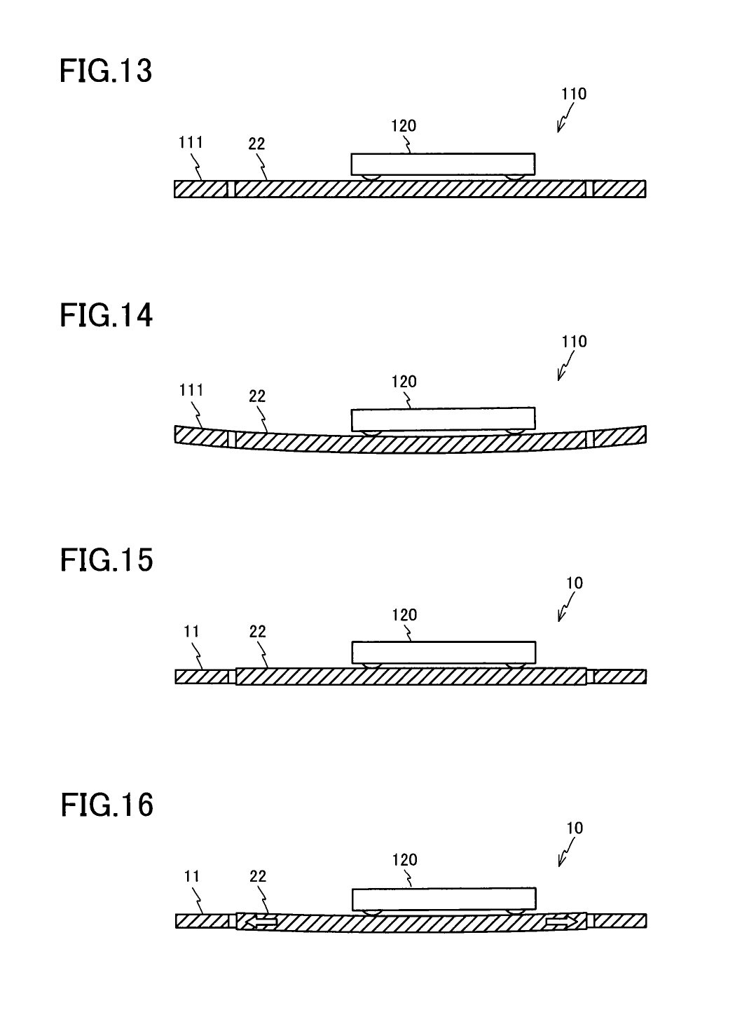

Hereinafter, the effects described above will be described with reference to the accompanying drawings. FIG. 13 is a diagram illustrating a cross section of the wiring substrate 110 which has a conventional piece substrate 22 and a frame 11 made of the same material as that of the piece substrate 22. As illustrated in FIG. 13, the piece substrate 22 is connected to the frame 11 and is accordingly supported by the frame 11.

The wiring substrate 110 is heated in the reflow process for mounting electronic components 120 on the piece substrate 22 of the wiring substrate 110. In this case, if the piece substrate 22 and the frame 111 that supports the piece substrate 22 are heated to a temperature equal to or higher than the glass transition temperature of their materials, the rigidity of the piece substrate 22 and the frame 111 may be degraded. As a result, the wiring substrate 110 warps as illustrated in FIG. 14 due to the weight of the electronic component 120 or thermal contraction of the resin of the piece substrate 22.

FIG. 15 is a diagram illustrating a cross section of the wiring substrate 10 according to the present embodiment with the electronic component 120 mounted on the piece substrate 22. In the wiring substrate 10 according to the present embodiment, a piece substrate 22 is supported by a frame 11 made of aluminum. Therefore, the rigidity of the frame 11 is maintained even when the piece substrate 22 and the frame 11 supporting the piece substrate 22 are heated to a temperature equal to or higher than the glass transition temperature of the resin of the piece substrate 22. In addition, unlike resin, the frame 11 does not thermally contract, but expands outwardly when it is heated. Accordingly, the piece substrate 22 outwardly expands by the frame 11 as illustrated in FIG. 16 even when the rigidity of the piece substrate 22 is degraded. Therefore, thermal warping of the piece substrate 22 is suppressed.

As described above, according to the present embodiment, the piece substrate 22 is supported by the frame 11 having high rigidity. For this reason, warping of the wiring substrate 10 that may occur in an electronic component mounting process and the like is suppressed. Therefore, accuracy of mounting electronic components on the wiring substrate 10 is improved. In addition, the conductive layer and the insulation layer on the piece substrate 22 of the wiring substrate 10 are laminated with high accuracy.

According to the present embodiment, the matching portion 101 is cut out from the work piece 100 by irradiating laser beam (LB) along the outer edge of the metal pattern 25 to manufacture the piece substrate 22 as illustrated in FIG. 7, for example. In the piece substrate 22 manufactured in this manner, the contour of the fitting portion (22a) corresponds to the outer edge of the metal pattern 25 as illustrated in FIG. 9. For this reason, by forming the metal pattern 25 on the work piece 100 in advance such that the contour of the concave portion (11a) formed in the frame 11 substantially corresponds to the outer edge of the metal pattern 25, the piece substrate 22 is manufactured having the fitting portions (22a) closely fitted into the concave portions (11a) of the frame 11. As a result, the accuracy of aligning the piece substrate 22 with the frame 11 is improved. Therefore, the accuracy of mounting electronic components on the wiring substrate 10 is improved. Furthermore, the conductive layer and the insulation layer on the piece substrate 22 of the wiring substrate 10 are laminated with high accuracy.

In the embodiment described above, the frame 11 may be repeatedly used by exchanging the piece substrate 22 accommodated in the frame 11. Accordingly, once the frame 11 is manufactured with the concave portions (11a) being positioned accurately, a positional relationship between the piece substrates 22 accommodated in the frame 11 is maintained constantly. Therefore, the wiring substrate 10 is continuously produced with high quality.

According to an embodiment of the present invention, unlike the technique described in JP 2011-23657 A, the portion corresponding to the frame 11 is not removed from the work piece 100, and production yield of the piece substrate for the work piece 100 can be improved.

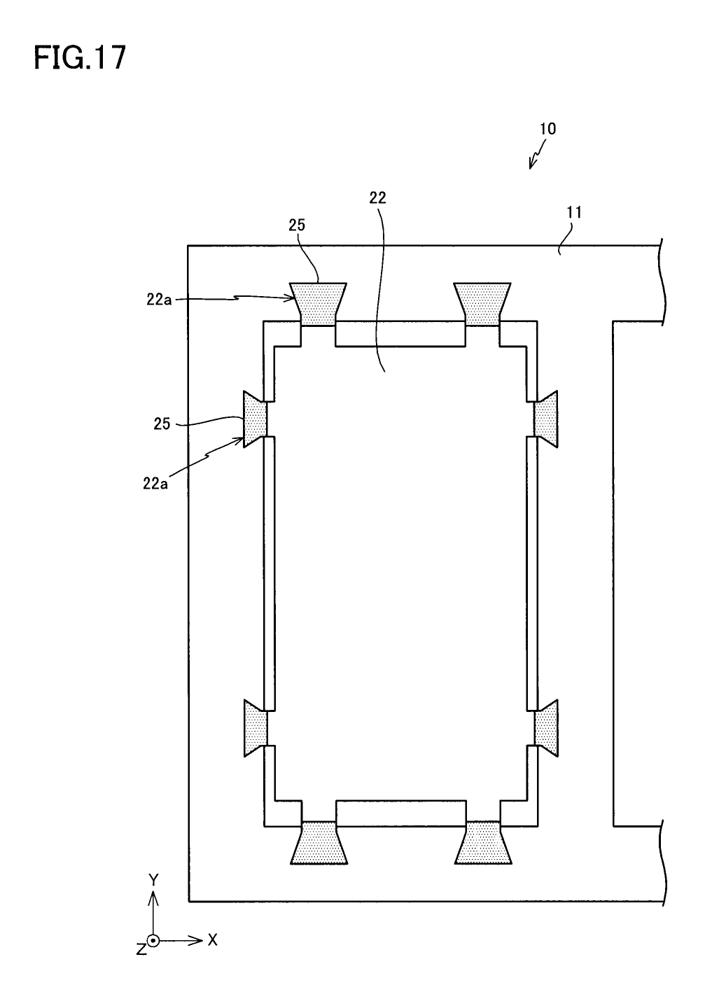

Embodiments of the invention have been described so far. However, the present invention is not limited to the above. For example, in the aforementioned embodiment, a case has been described where the metal pattern 25 is formed on the entire outer edge of the matching portion 101 of the work piece 100 as illustrated in FIG. 7. However, the present invention is not limited to that. For example, as illustrated in FIG. 17, the metal pattern 25 may be formed only on the outer edge of the fitting portion (22a) of the piece substrate 22. Even in this case, the matching portion 101 is cut out such that the outer edge of the matching portion 101 corresponding to the fitting portion (22a) of the piece substrate 22 matches the contour of the concave portion (11a) of the frame 11. Therefore, the piece substrate 22 is accommodated in the frame 11 with high accuracy.

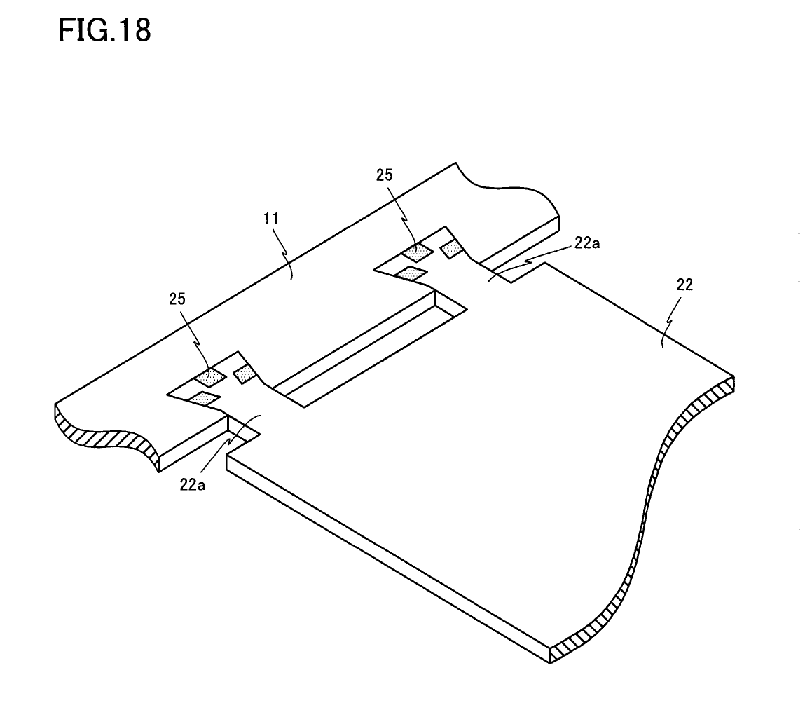

In the aforementioned embodiment, a case has been described where the metal pattern 25 is formed on the entire outer edge of the fitting portion (22a) of the piece substrate 22. However, the invention is not limited to that. For example, as illustrated in FIG. 18, the metal pattern 25 may be divided into portions to be located along the outer edge of the fitting portion (22a) of the piece substrate 22. Even in this case, the outer edge of the fitting portion (22a) where the metal pattern 25 is formed corresponds to the contour of the concave portion (11a) of the frame 11. Therefore, the piece substrate 22 in the frame 11 is accommodated with high accuracy.

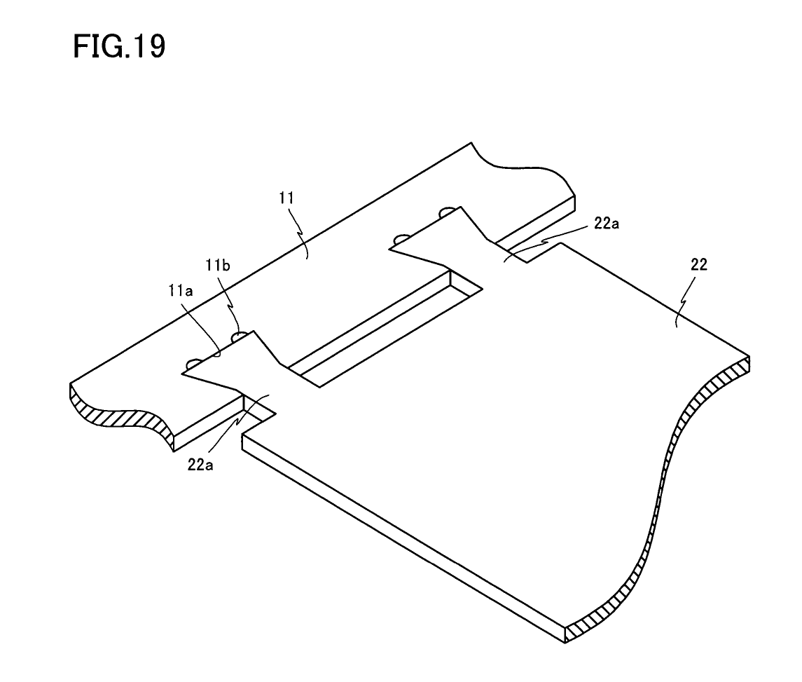

In the aforementioned embodiment, a case has been described where the piece substrate 22 and the frame 11 are bonded to each other using an adhesive that enters a gap between the inner wall surface of the concave portion (11a) formed in the frame 11 and the side surface of the fitting portion (22a) formed in the piece substrate 22. However, the present invention is not limited to that. For example, as illustrated in FIG. 19, a cavity (11b) may be provided in the concave portion (11a) of the frame 11, and the piece substrate 22 and the frame 11 may be bonded to each other by filling an adhesive into the cavity (11b).

In the aforementioned embodiment, a case has been described where the metal pattern 25 is formed on the upper surface of the piece substrate 22. Alternatively, this metal pattern 25 may be a part of the conductor pattern connected to the electronic component. In addition, the insulation layer may be formed on the upper surface of the metal pattern 25. Even in this case, the matching portion 101 is cut out from the work piece 100 along the metal pattern 25 with high accuracy.

In the aforementioned embodiment, a case has been described where the piece substrate 22 is connected to the frame 11 using eight fitting portions (22a). However, the present invention is not limited to that. Alternatively, seven or less, or nine or more fitting portions may also be formed in the piece substrate 22.

In the aforementioned embodiment, a case has been described where a UV-curable adhesive is employed to bond the frame 11 and the piece substrate 22. However, the present invention is not limited to that. Alternatively, a thermosetting adhesive may also be employed to bond the frame 11 and the piece substrate 22. In addition, two or more types of adhesives may also be employed. For example, a photo-curable adhesive or an acryl-based adhesive may be applied in the bonding (preliminary bonding), and then, a thermosetting adhesive may be applied to reinforce the bonding.

In the aforementioned embodiment, a case has been described where the concave portion (11a) is formed in the frame 11 of the wiring substrate 10, and the outwardly protruding fitting portion (22a) is formed in the piece substrate 22. However, the present invention is not limited to that. Alternatively, the concave portion may be formed in the piece substrate 22, and the fitting portion fitted into the concave portion formed in the piece substrate 22 may be formed in the frame 11.

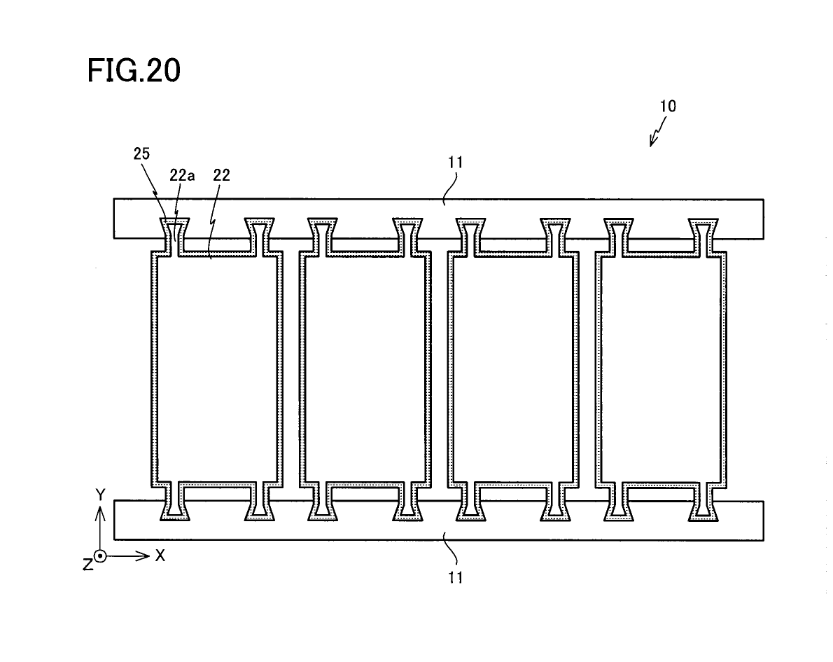

In the aforementioned embodiment, a rectangular frame is employed as the frame 11. However, the shape of the frame 11 is not limited to that. For example, as illustrated in FIG. 20, multiple piece substrates 22 may be integrated into a single body using a bar-like frame 11.

The process according to the aforementioned embodiment is not limited to the sequence illustrated in the flowchart. The sequence may be modified freely as long as it does not deviate from the concept and scope of the present invention. In addition, a part of the process may be omitted depending on application.

In the aforementioned embodiment, the frame 11 is made of aluminum. However, the present invention is not limited to that. Alternatively, the frame 11 may be made of materials such as stainless steel or iron other than aluminum.

In the aforementioned embodiment, the piece substrate 22 is a rigid wiring board including an insulation layer and a conductive layer. However, a structure of the piece substrate 22 is not limited to that. Alternatively, the wiring board may be obtained by alternately laminating a wiring layer and an insulation layer on a ceramic substrate. The piece substrate 22 is not limited to the rigid wiring board. The piece substrate 22 may be a flexible wiring board or a flex-rigid wiring board. Furthermore, the piece substrate 22 may have any shape. The piece substrate 22 may have, for example, a parallelogram shape, a circular shape, an elliptical shape, or the like.

In the aforementioned embodiment, a case has been described where the piece substrate 22 includes an interlayer insulation layer and a conductive pattern. However, the present invention is not limited to that. Alternatively, the piece substrate 22 may be a substrate with a component built into the base material 70. In addition, the piece substrate 22 may include multiple subsidiary pieces.

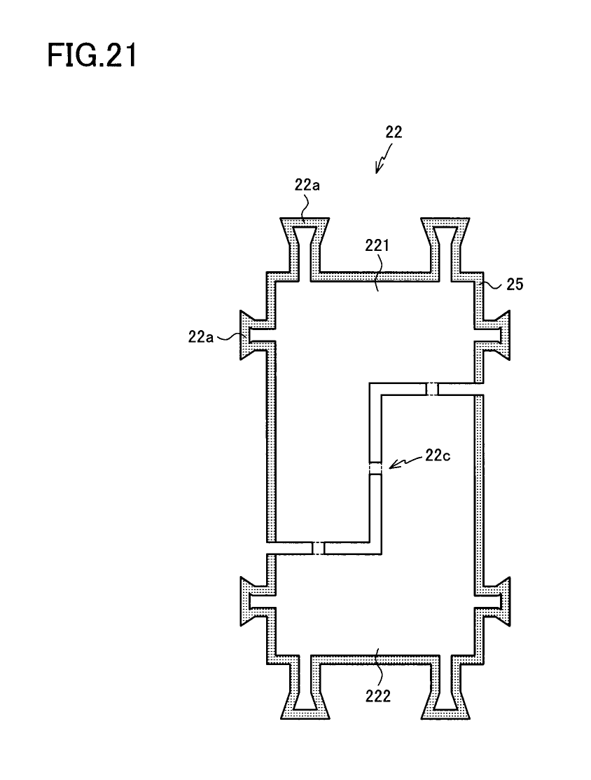

Specifically, as illustrated in FIG. 21, the piece substrate 22 may include a pair of subsidiary piece substrates (221, 222). As illustrated in FIG. 21, each of the subsidiary piece substrates (221, 222) is an L-shaped wiring board. Such subsidiary piece substrates (221, 222) are connected to each other through bridges (22c) formed in three portions of the piece substrate 22.

The piece substrate 22 structured as described above is cut out from the work piece 100 while the subsidiary piece substrates (221, 222) are connected to each other through the bridges (22c). In this piece substrate 22, the metal pattern 25 is formed along the outer edge of the piece substrate 22.

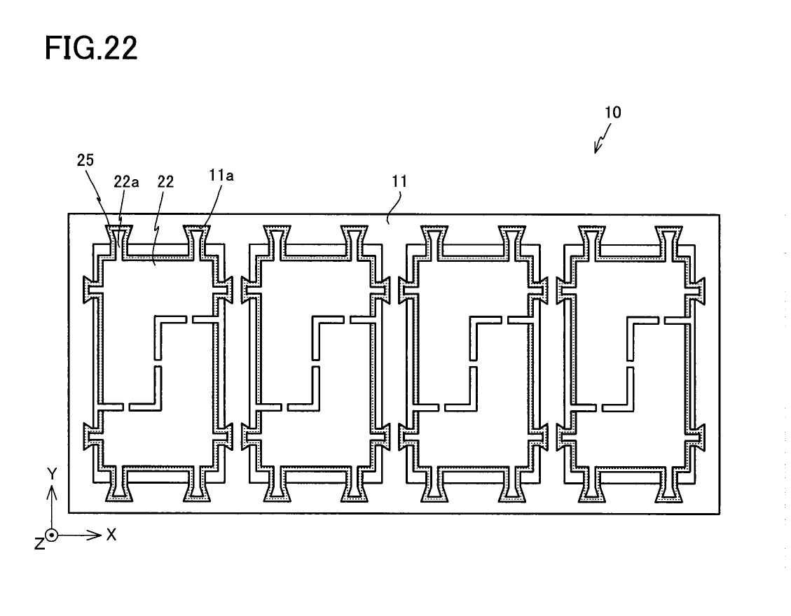

The piece substrate 22 including a pair of subsidiary piece substrates (221, 222) is accommodated in the frame 11 by inserting the fitting portions (22a) of the piece substrate 22 into the concave portions (11a) of the frame 11 as illustrated in FIG. 22 to form the wiring substrate 10.

As described above, if the piece substrate 22 includes multiple subsidiary piece substrates (221, 222), lithography can be performed simultaneously on the piece substrates having a desired shape by using a common frame 11.

Multiple subsidiary piece substrates (221, 222) described above have the same shape as illustrated in FIG. 21. However, a combination of subsidiary piece substrates having different shapes may also be used in the piece substrate 22.

In the aforementioned embodiment, a case has been described where the piece substrate 22 is manufactured by cutting out the matching portion 101 from the work piece 100. However, the present invention is not limited to that. Alternatively, the piece substrate 22 may be separated from another piece substrate as a base material.

In a reflow process of a multipiece substrate, a piece substrate or a frame that supports the piece substrate is heated to a temperature equal to or higher than a glass transition temperature of resin of the multipiece substrate. Thus, it is thought that the piece substrate warps under the influence of the weight of an electronic component mounted on the piece substrate of the multipiece substrate or residual stress on the piece substrate.

A wiring substrate according to an embodiment of the present invention suppresses warping of a piece substrate by improving the rigidity of the frame that supports the piece substrate.

According to a first aspect of the invention, there is provided a wiring substrate that includes: a frame that is made of a metal material and has a connecting portion; and a piece substrate that is connected to the connecting portion and has a metal pattern having a contour corresponding to an outer edge of the connecting portion.

According to another aspect of the invention, there is provided a method for manufacturing a substrate board, including: preparing a frame that is made of a metal material and has a connecting portion; preparing a base material having a matching portion to be cut out as a piece substrate; in the base material, forming a metal pattern having an outer edge corresponding to a contour of the connecting portion to which the matching portion is connected; separating the piece substrate from the base material by irradiating a laser beam onto a boundary between the base material and the metal pattern; and accommodating the piece substrate in the frame by inserting into the connecting portion a fitting portion formed in the piece substrate by separating the piece substrate from the base material.

According to an embodiment of the present invention, the piece substrate of the wiring substrate is supported by a frame made of a metal material that exhibits higher rigidity at high temperatures than that of glass or epoxy resin used in the piece substrate. Thus, warping of the piece substrate occurring in a lithography process of the wiring substrate is suppressed.

In addition, a metal pattern corresponding to an outer edge of a connecting portion of the frame is formed in the piece substrate. As a result, the alignment accuracy of the piece substrate relative to the frame is improved.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring substrate, comprising:
a frame comprising a metal material and having a connecting portion; and
a piece substrate connected to the connecting portion of the frame and having a metal pattern,
wherein the metal pattern of the piece substrate has a contour which is corresponding to an outer edge of the connecting portion of the frame.

2. The wiring substrate according to claim 1, wherein the frame has a thickness which is less than a thickness of the piece substrate.

3. The wiring substrate according to claim 2, wherein the piece substrate comprises a pair of substrates.

4. The wiring substrate according to claim 3, wherein each of the substrates has a first portion and a second portion, and the pair of substrates is formed such that the first portion of one of the substrates is positioned beside the second portion of the other one of the substrates.

5. The wiring substrate according to claim 1, wherein the piece substrate has a fitting portion configured to engage with the connecting portion of the frame, and the metal pattern of the piece substrate is formed in the fitting portion of the piece substrate.

6. The wiring substrate according to claim 5, wherein the piece substrate has a main body, and the fitting portion of the piece substrate is projecting outward from the main body of the piece substrate.

7. The wiring substrate according to claim 1, wherein the metal pattern of the piece substrate is formed on a surface of the piece substrate.

8. The wiring substrate according to claim 1, wherein the metal pattern of the piece substrate is configured to block laser irradiation.

9. The wiring substrate according to claim 1, wherein the piece substrate is connected to the frame such that the piece substrate is adhered to the connecting portion of the frame.

10. The wiring substrate according to claim 1, wherein the frame has an opening portion, and the piece substrate is accommodated in the opening portion of the frame.

11. The wiring substrate according to claim 10, wherein the piece substrate has four corner portions through which the piece substrate is connected to the frame.

12. A method for manufacturing a wiring substrate, comprising:
providing a frame comprising a metal material and having a connecting portion;
providing a base component having a corresponding portion configured to be cut and form a piece substrate;
forming a metal pattern on the base component such that the metal pattern is configured to correspond to an outer edge of a fitting portion of the corresponding portion for connecting with the connecting portion of the frame;
irradiating laser along a border formed between the metal pattern and the base component such that the piece substrate comprising the corresponding portion is cut out from the base component; and
engaging the fitting portion of the piece substrate to the connecting portion of the frame such that the piece substrate is connected to the frame.

13. The method for manufacturing a wiring substrate according to claim 12, wherein the providing of the frame includes forming the frame such that the frame has a thickness which is set less than a thickness of the piece substrate.

14. The method for manufacturing a wiring substrate according to claim 12, wherein the piece substrate is formed such that the piece substrate comprises a pair of substrates.

15. The method for manufacturing a wiring substrate according to claim 14, wherein each of the substrates has a first portion and a second portion, and the pair of substrates is formed such that the first portion of one of the substrates is positioned beside the second portion of the other one of the substrates.

16. The method for manufacturing a wiring substrate according to claim 12, wherein the piece substrate is formed such that the piece substrate has a main body and that the fitting portion of the piece substrate is projecting outward from the main body of the piece substrate.

17. The method for manufacturing a wiring substrate according to claim 12, wherein the metal pattern of the piece substrate is formed on a surface of the piece substrate.

18. The method for manufacturing a wiring substrate according to claim 12, wherein the metal pattern of the piece substrate is formed such that the metal pattern of the piece substrate is configured to block laser irradiation.

19. The method for manufacturing a wiring substrate according to claim 12, wherein the piece substrate is connected to the frame such that the piece substrate is adhered to the connecting portion of the frame.

20. The method for manufacturing a wiring substrate according to claim 12, wherein the base component comprises a wiring substrate comprising the piece substrate.

21. The method for manufacturing a wiring substrate according to claim 12, wherein the frame has an opening portion, and the piece substrate is accommodated in the opening portion of the frame.

22. The method for manufacturing a wiring substrate according to claim 21, wherein the piece substrate has four corner portions through which the piece substrate is connected to the frame.
